(19) United States
(12) Patent Application Publication
(10) Pub. No.: US 2025/0130267 A1
(43) Pub. Date: Apr. 24, 2025

(54) Methods, Apparatuses and Composite Power Switch Capable of Detecting Conduction Current Flowing Through Power Switch

(71) Applicant: Weltrend Semiconductor Inc., Hsinchu (TW)

(72) Inventor: Hui-Yuan HSU, Hsinchu (TW)

(21) Appl. No.: 18/636,764

(22) Filed: Apr. 16, 2024

(30) Foreign Application Priority Data
Oct. 23, 2023 (TW) 112140432

(51) Int. Cl. G01R 31/26; H03K 17/08

(52) U.S. Cl. CPC G01R 31/2601; H03K 17/08; H03K 2217/0027

(57) ABSTRACT

Disclosed is an apparatus for detecting a conduction current flowing through a power switch with a control node, a channel node and a reference node. The apparatus has a voltage detector, a current detector and a close-loop controller. The voltage detector transmits a channel voltage at the channel node to a voltage detection node as a detection voltage when the power switch is turned ON, makes the detection voltage different from the channel voltage when the power switch is turned OFF. The current detector is coupled to the control node and the reference node to form a current mirror with a current detection node. The close-loop controller provides an emulation current to the current detection node to make a controlled voltage at the current detection node equal to the detection voltage.

### CROSS-REFERENCE TO RELATED APPLICATION

This application claims priority to and the benefit of Taiwan Application Series Number 112140432 filed on Oct. 23, 2023, which is incorporated by reference in its entirety.

### BACKGROUND

The present disclosure relates generally to detecting a conduction current flowing through a power switch, and more particularly, to apparatuses and methods that produce an output current proportional to the conduction current flowing through a power switch.

Power switches are used to conduct large currents and are often employed to control the current flowing through inductors or capacitors. In terms of control, the current flowing through power switches should be precisely detected, for example, to ensure that an inductor does not fail due to excessive current leading to magnetic saturation.

FIG. 1 illustrates how the prior art detects the conduction current IN1 flowing through the power switch N1. Power switches N1 and N2 (two NMOS transistors) generally have similar structures. Essentially, under the same gate-to-source voltage and drain-to-source voltage, the currents conducted by power switches N1 and N2 should be proportional, for example, in a ratio of 100:1. When power controller 102 provides control signal VG of about 20 volts through control terminal DRV, turning ON power switches N1 and N2, current sense signal VCS roughly reflects detected current ICS. By the proportional relationship between current IN1 and detected current ICS, the current flowing through inductor L (equal to the sum of current IN1 and detected current ICS) can be roughly inferred.

However, in FIG. 1, power switches N1 and N2 do not have completely identical gate-to-source voltage VGS and drain-to-source voltage VDS. Therefore, it is not possible to confirm the proportional relationship between the currents conducted by power switches N1 and N2 entirely. From FIG. 1, when power switches N1 and N2 are turned ON, the source S of power switch N1 has the voltage of 0V, grounded. In contrast, the source S of power switch N2 has the voltage of current sense signal VCS, which changes with detected current ICS. For example, if control signal VG is 20V, and current sense signal VCS is 0.4V, the gate-to-source voltage VGS of power switch N1 is 20V, while the gate-to-source voltage VGS of power switch N2 is 19.6V. These values are not the same. Similarly, in FIG. 1, when current sense signal VCS is not 0V, power switches N1 and N2 also do not have completely identical drain-to-source voltage VDS. Therefore, power controller 102 in FIG. 1 cannot accurately deduce the inductor current flowing through inductor L based on current sense signal VCS.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIG. 1 illustrates how the prior art detects the conduction current flowing through a power switch;

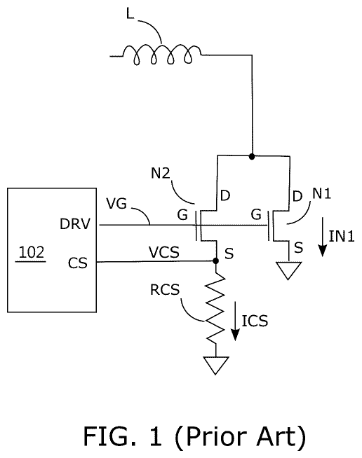

FIG. 2 illustrates an apparatus according to an embodiment of the present invention, used to detect a conduction current through a power switch;

FIG. 3 illustrates a top view of a composite power switch formed on a substrate according to embodiments of the invention;

FIGS. 4 and 5 show apparatuses according to embodiments of the invention;

FIG. 6 illustrates a power supply according to embodiments of the invention; and

FIG. 7 illustrates an apparatus according to embodiments of the invention, designed to detect a conduction current flowing through a PMOS power switch.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure, or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures, or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

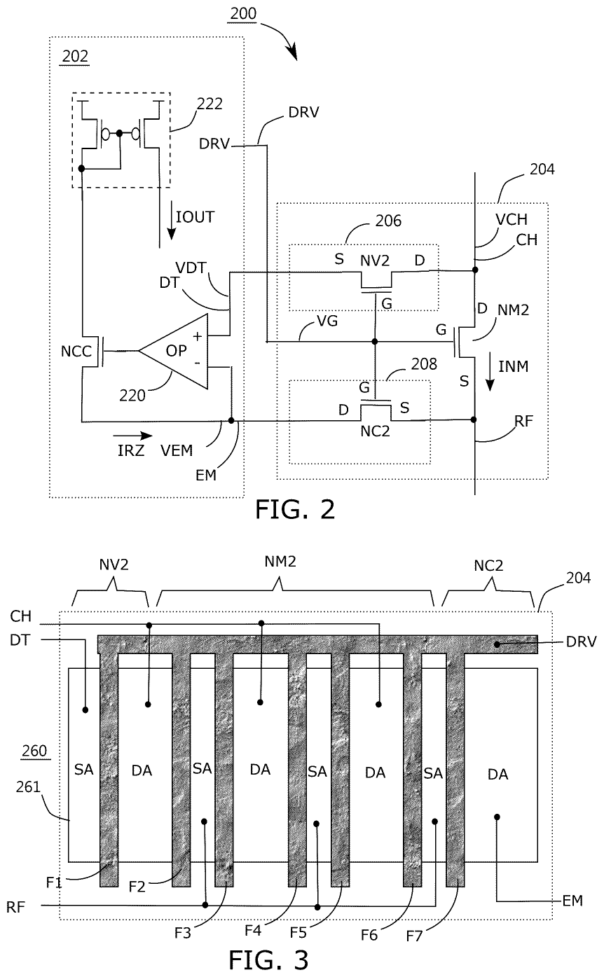

FIG. 2 illustrates apparatus 200 according to an embodiment of the present invention, used to detect conduction current INM flowing through power switch NM2. Apparatus 200 includes voltage detector 206, current detector 208, and closed-loop controller 202. Power switch NM2 in FIG. 2 is an NMOS transistor, but the present invention is not limited to. In other embodiments, power switch NM2 can be a PMOS transistor, field-effect transistor, gallium nitride (GAN) transistor, silicon carbide (SiC) transistor, or other semiconductor power switches.

The drain (D), source(S), and gate (G) of the power switch NM2 serve as the channel node (CH), reference node (RF), and control node (DRV), respectively. Control signal VG at control node DRV can turn ON or turn OFF power switch NM2. When power switch NM2 is ON, it provides a low-impedance conductive path, electrically connecting channel node CH and reference node RF. When power switch NM2 is OFF, this conductive path transitions to high impedance, electrically isolating channel node CH from reference node RF.

As shown in FIG. 2, voltage detector 206 and current detector 208 correspond to power switches NV2 and NC2, respectively. In one embodiment, power switches NM2, NV2, and NC2 construct composite power switch 204 which is formed on a common semiconductor substrate. Composite power switch 204 provides control node DRV, channel node CH, reference node RF, voltage detection node DT, and current detection node EM. In the embodiment of FIG. 2, each of power switches NM2, NV2, and NC2 is an NMOS transistor with a gate (G), a drain (D), and a source(S). The gates (G) of power switches NM2, NV2, and NC2 are electrically connected to each other, serving as control node DRV for composite power switch 204. The drains (D) of power switches NM2 and NV2 are electrically connected, serving as channel node CH. The source(S) of power switch NV2 serves as voltage detection terminal DT. The sources(S) of power switches NM2 and NC2 are electrically connected, serving as reference node RF. The drain (D) of NC2 serves as current detection terminal EM.

As shown in FIG. 2, voltage detector 206 is electrically connected to channel node CH and control node DRV. When control signal VG turns ON power switch NM2, power switch NV2 in voltage detector 206 is also ON. Therefore, channel voltage VCH at channel node CH is transmitted to voltage detection terminal DT, becoming detection voltage VDT. When control signal VG turns OFF power switch NM2, power switch NV2 in the voltage detector 206 is also OFF, so detection voltage VDT is different from channel voltage VCH.

Current detector 208 is electrically connected to reference node RF and control node DRV, and provides current detection node EM. In FIG. 2, when control signal VG turns ON/OFF power switch NM2, it simultaneously turns ON/OFF power switch NC2.

Closed-loop controller 202 is electrically connected to current detection node EM and voltage detection node DT, and provides emulation current (IRZ) to current detection node EM to make controlled voltage VEM at current detection terminal EM approximately equal to detection voltage VDT. As shown in FIG. 2, closed-loop controller 202 includes operational amplifier 220, NMOS transistor NCC, and current mirror 222. Operational amplifier 220 acts as a differential amplifier. When detection voltage VDT and controlled voltage VEM at the non-inverted and inverted differential inputs are different, operational amplifier 220 controls NMOS transistor NCC, acting as a controllable current source, to change emulation current IRZ provided by NMOS transistor NCC. Emulation current IRZ flows through current detection terminal EM to power switch NC2, causing controlled voltage VEM to be approximately equal to the detection voltage VDT. For example, if detection voltage VDT is greater than controlled voltage VEM, operational amplifier 220 increases the gate voltage of NMOS transistor NCC, increasing emulation current IRZ, resulting in an increase in controlled voltage VEM, which approaches detection voltage VDT. This way, the closed-loop provided by closed-loop controller 202 can roughly maintain controlled voltage VEM approximately equal to detection voltage VDT. Current mirror 222 mirrors emulation current IRZ to generate output current IOUT, which serves as the output of closed-loop controller 202.

When control signal VG turns ON power switch NM2, output current IOUT can be quite accurately proportional to conduction current INM flowing through power switch NM2. When control signal VG turns ON power switch NM2, power switches NV2 and NC2 are also ON, and detection voltage VDT is approximately equal to channel voltage VCH. Closed-loop controller 202 makes controlled voltage VEM approximately equal to detection voltage VDT. Therefore, power switch NM2 and power switch NC2 will have approximately the same gate-to-source voltage (VGS) and drain-to-source voltage (VDS). As long as power switches NM2 and NC2 have similar structures, these two power switches can form a current mirror, conduction current INM and emulation current IRZ will exhibit a proportional relationship, so output current IOUT is also linearly proportional to conduction current INM.

When control signal VG turns OFF power switch NM2, voltage detector 206 can prevent excessive channel voltage VCH at channel node CH from damaging the electronic components inside the closed-loop controller 202. For example, when control signal VG and reference node RF are both 0V, and power switch NM2 is turned off, channel voltage VCH may rise to 500V due to the charging of an inductor current. At this moment, power switch NV2 inside voltage detector 206 is also turned off, so detection voltage VDT at the source S of the power switch NV2 may be only 0V, completely different from channel voltage VCH, which is 500V. As long as power switch NV2 is a high-voltage tolerant component, power switch NV2 and closed-loop controller 202 will not be damaged by this excessively high channel voltage VCH.

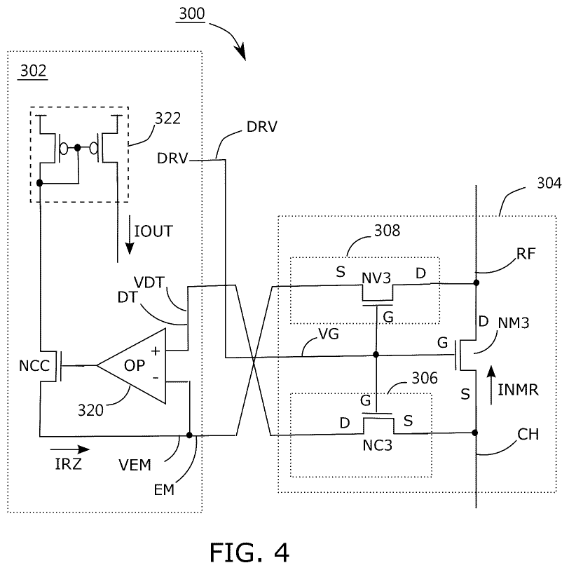

FIG. 3 illustrates a top view of composite power switch 204 formed on substrate 260 of a semiconductor chip according to embodiments of the invention. The finger-shaped gate structure has several fingers F1 to F7, together serving as control node DRV of composite power switch 204. Each finger can be considered as a gate of a transistor, separating a drain area DA and a source area SA, and is also used to control the electrical connection between the drain area DA and the source area SA. All drain areas DA and sources SA are formed within common active region 261, which in FIG. 3 is surrounded by a field oxide layer or a shallow trench layer. It seems like in FIG. 3 fingers F1 to F7 divide common active region 261 to form drain areas DA and sources SA. Finger F1 roughly serves as gate G of power switch NV2, and the source area SA at the left side of finger F1 serves as voltage detection node DT and source S of power switch NV2. Similarly, finger F7 roughly serves as gate G of power switch NC2, and the drain area DA at the right side of finger F7 serves as current detection node EM and source D of power switch NC2. Fingers F2 to F6 serve as the gate G of the power switch NM2, the source areas SA between the fingers F2 and F7 are electrically connected as reference node RF, and the drain areas DA between the fingers F1 and F6 are electrically connected as channel node CH. In a cross-sectional view of FIG. 3, it can be observed that power switches NM2, NC2, and NV2 have similar structures. Therefore, as long as power switches NM2, NC2, and NV2 have the same gate-to-source voltage VGS and drain-to-source voltage VDS, the currents flowing through power switches NM2, NC2, and NV2 will be approximately in a fixed proportional relationship, forming a current mirror.

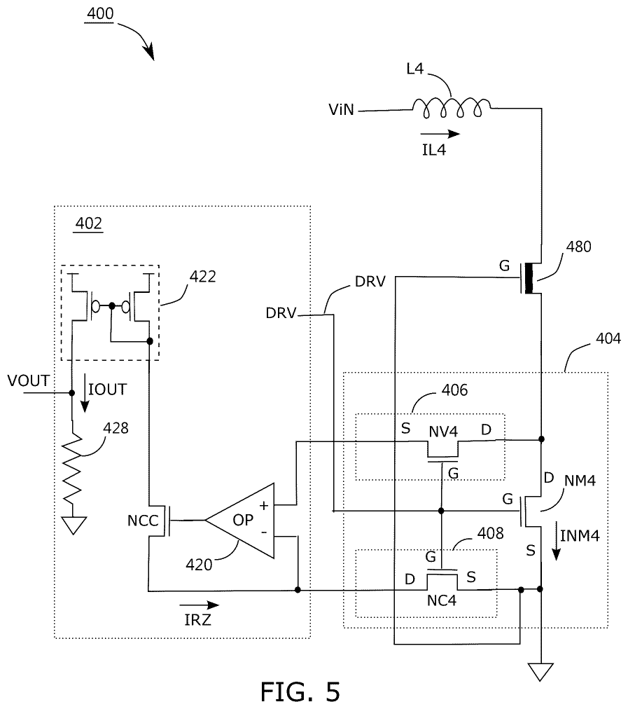

Apparatus 200 in FIG. 2 can be used to detect conduction current INM flowing through power switch NM2 when it is positive, flowing from drain D of power switch NM2 to source S of power switch NM2. FIG. 4 shows apparatus 300 according to embodiments of the invention, which can be used to detect conduction current INMR flowing through the power switch NM3, with a direction opposite to conduction current INM of power switch NM2 in FIG. 2. Many features of FIG. 4 are similar or identical to those in FIG. 2, and can be understood through the previous descriptions without further explanation.

As widely understood in the art, in terms of electrical characteristics, the source of an NMOS transistor generally refers to one of the two ends of the controllable conductive channel, whichever has a relatively lower voltage. In FIG. 2, because of the direction of conduction current INM, channel voltage VCH at drain D (channel node CH) of power switch NM2 is higher than the voltage at source S (reference node RF) of power switch NM2. In contrast, in FIG. 4, because conduction current INMR flows from source S to drain D of power switch NM3, drain D of power switch NM3 plays the role of a source in terms of electrical characteristics, and source S of the power switch NM3 plays the role of a drain in terms of electrical characteristics. Therefore, as shown in FIG. 4, drain D of power switch NM3 becomes reference node RF, source S of power switch NM3 becomes channel node CH, power switch NV3 becomes current detector 308, and power switch NC3 becomes voltage detector 306. Similar to the operations explained previously for FIG. 2, in FIG. 4, closed-loop controller 302 is electrically connected to current detection node EM and voltage detection node DT, and provides emulation current IRZ to current detection node EM, so that the controlled voltage VEM at current detection node EM is approximately equal to detection voltage VDT. Output current IOUT generated by current mirror 322 will be linearly proportional to conduction current INMR.

Anyone of apparatus 200 in FIG. 2 and apparatus 300 in FIG. 4 can be applied to high-side power switch current detection or low-side power switch current detection. Generally, a high-side power switch refers to a power switch used to control the current flowing into/from a high-voltage power line, and a low-side power switch refers to a power switch used to control the current flowing into/from a ground power line.

FIG. 5 illustrates apparatus 400 according to embodiments of the invention, implementing the current detection for a low-side power switch. Many features of FIG. 5 are similar or identical to those in FIG. 2, and can be understood through the previous descriptions without further explanation.

Power switch NM4 and depletion-mode gallium nitride (GAN) transistor 480 form a cascode configuration, serving as a low-side power switch connected between the inductor L4 and a ground power line. The gate G of GAN transistor 480 is connected to the source S of power switch NM4. Inductor L4 is connected to input power line VIN. Composite power switch 404 includes power switches NM4, NV4, and NC4. Output current IOUT provided by closed-loop controller 402 flows through resistor 428, generating output voltage VOUT. As explained earlier, when power switch NM4 is ON, output voltage VOUT is roughly proportional to conduction current INM4 flowing through power switch NM4, which is equal to inductor current IL4 flowing through inductor L4.

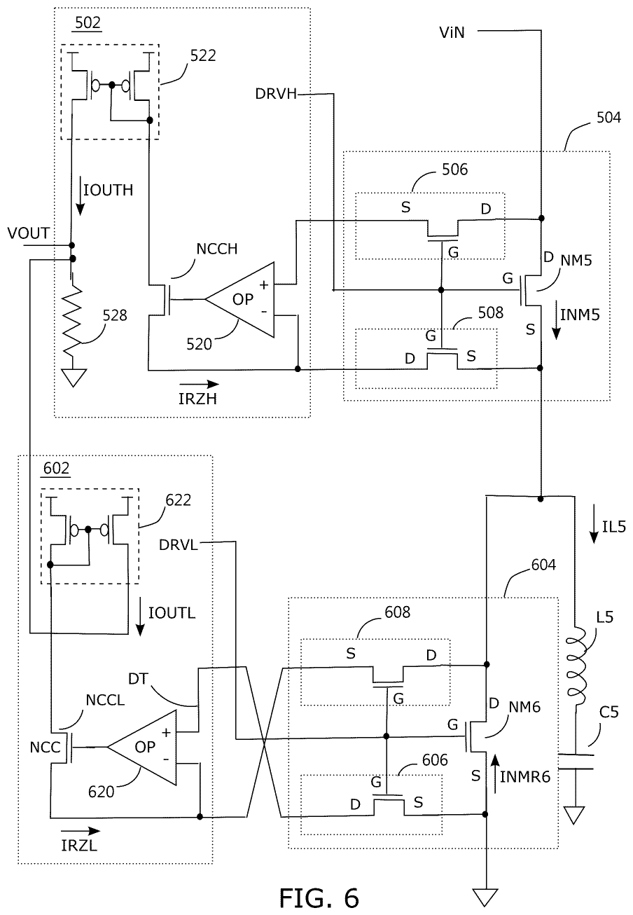

FIG. 6 illustrates an embodiment of the invention, which could be an LLC resonant power supply or an asymmetric half-bridge (AHB) power supply. Power switches NM5 and NM6 are the high-side and low-side switches of a half-bridge connected between the input power line VIN and the ground power line. Power switches NM5 and NM6 drive a resonant circuit composed of inductor L5 and capacitor C5. Closed-loop controller 502 and composite power switch 504 implement high-side switch current detection, many parts of which can be understood through apparatus 200 previously taught in FIG. 2 and will not be redundantly explained. Closed-loop controller 602 and composite power switch 604 implement low-side switch current detection, many parts of which can be understood through apparatus 300 in FIG. 4 and will not be detailed hereinafter.

In FIG. 6, when power switch NM5 is ON and power switch NM6 is OFF, power switch NM5 provides conduction current INM5 to charge inductor L5 and capacitor C5, where the inductor current IL5 is equal to conduction current INM5. Output current IOUTH provided by current mirror 522 is proportional to inductor current IL5, while output current IOUTL provided by current mirror 622 is about 0 A because no current flows through current detector 608. Output currents IOUTH and IOUTL together flow through resistor 528. Therefore, when power switch NM5 is ON and power switch NM6 is OFF, output voltage VOUT is approximately proportional to inductor current IL5.

When power switch NM5 is OFF and power switch NM6 is ON, power switch NM6 provides current INMR6 as inductor current IL5 flowing through inductor L5. At this time, output current IOUTL provided by current mirror 622 is proportional to inductor current IL5, but output current IOUTH provided by the current mirror 522 is about 0 A because no current flows through current detector 508. Output currents IOUTH and IOUTL together flow through the resistor 528. Therefore, when power switch NM5 is OFF and power switch NM6 is ON, output voltage VOUT is still approximately proportional to inductor current IL5.

In other words, output voltage VOUT in FIG. 6 can faithfully reflect inductor current IL5 during the process of charging or discharging inductor L5.

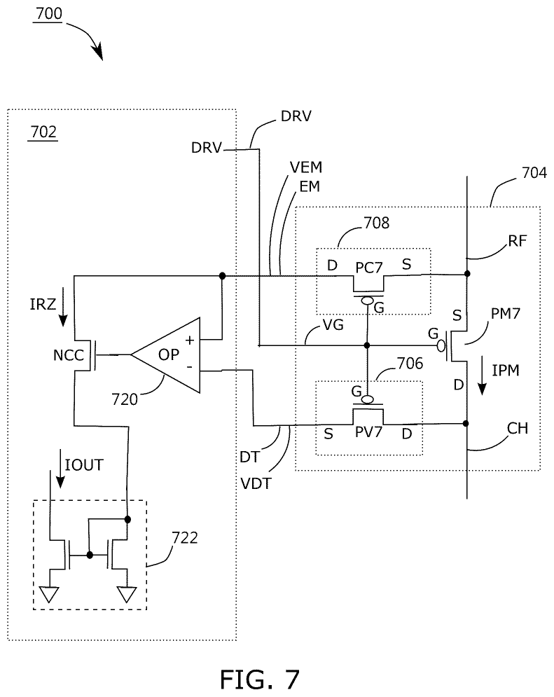

FIG. 7 illustrates apparatus 700 according to embodiments of the invention, designed to detect conduction current IPM flowing through power switch PM7, where power switch PM7 is a PMOS transistor. Parts of apparatus 700 are similar to or the same as those in apparatus 200, and might not be detailed in view of the previous teaching of apparatus 200.

Apparatus 700 includes voltage detector 706, current detector 708, and closed-loop controller 702. Composite power switch 704 is formed on a semiconductor substrate of an integrated circuit and includes power switches PM7, PC7, and PV7, all of which are PMOS transistors. Operational amplifier 720 in closed-loop controller 702 controls NMOS transistor NCC, providing emulation current IRZ that flows through power switch PC7 in current detector 708, in order to make controlled voltage VEM approximately equal to detection voltage VDT. Through a current mirror formed by power switches PM7 and PC7, emulation current IRZ is proportional to conduction current IPM. Current mirror 722 causes output current IOUT to be proportional to emulation current IRZ. Therefore, output current IOUT is proportional to conduction current IPM.

The present invention can accurately detect the conduction current of a power switch when the power switch is ON. At the same time, it prevents possible damage to internal circuits caused by an excessively-high channel voltage on the power switch when it is turned off.

While the invention has been described by way of examples and in terms of preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An apparatus capable of detecting a conduction current flowing through a power switch, wherein the power switch comprises a control node, a channel node and a reference node, a control signal at the control node electrically connecting the channel node with the reference node or disconnecting the channel node from the reference node, the conduction current flowing through the channel node and the reference node, the apparatus comprising:
a voltage detector for transmitting a channel voltage at the channel node to a voltage detection node as a detection voltage when the power switch is turned ON, and for making the detection voltage different from the channel voltage when the power switch is turned OFF;
a current detector electrically coupled to the control node and the reference node, providing a current detection node; and
a close-loop controller electrically connected to the current detection node and the voltage detection node, for providing an emulation current to the current detection node to make a controlled voltage at the current detection node equal to the detection voltage.

2. The apparatus of claim 1, wherein the power switch is a first power switch; the current detector includes a second power switch; each power switch has a gate, a source and a drain; the two gates of the first and second power switches are electrically connected to serve as the control node; the two sources of the first and second power switches are electrically connected to serve as the reference node; and the drain of the second power switch serves as the current detection node.

3. The apparatus of claim 2, wherein the voltage detector includes a third power switch, the drains of the first and third power switches are electrically connected to serve as the channel node; the gates of the first, second and third power switches are electrically connected to serve as the control node; and the source of the third power switch is the voltage detection node.

4. The apparatus of claim 1, wherein the close-loop controller comprises a differential amplifier and a controllable current source, the controlled voltage and the detection voltage are provided to the differential amplifier as two inputs to control the controllable current source supplying the emulation current to the current detection node.

5. The apparatus of claim 1, wherein the power switch is a first power switch, the current detector provides a second power switch, and the first and second power switch form a current mirror when the first power switch is turned ON.

6. The apparatus of claim 1, wherein the close-loop controller comprises a current mirror to provide an output current mirroring the emulation current as an output of the close-loop controller.

7. The apparatus of claim 1, wherein the power switch is an N-type transistor, and the control, channel and reference nodes are the gate, drain and source of the N-type transistor.

8. The apparatus of claim 1, wherein the power switch is an N-type MOS transistor, a P-type MOS transistor, a field-effect transistor, a gallium nitride transistor, or a silicon carbide transistor.

9. The apparatus of claim 1, wherein the power switch is a first power switch, the voltage detector includes a second power switch, the current detector includes a third power switch, and the first, second, and third power switches are formed on a common substrate.

10. The apparatus of claim 9, wherein the first, second and third power switches have drain and source areas within a common active region on the common substrate.

11. A method for detecting a conduction current through a power switch with control, channel and reference nodes, the method comprising:
turning ON the power switch to electrically connecting the channel node with the reference node;
transmitting a channel voltage at the channel node to a voltage detection node as a detection voltage when the power switch is turned ON;
turning OFF the power switch is electrically disconnecting the channel node from the reference node;
making the channel voltage different from detection voltage when the power switch is turned OFF;
electrically coupling a current detector to the reference node and the control node, wherein the current detector provides a current detection node; and
providing an emulation current to the current detection node to make a controlled voltage at the current detection node substantially equal to the detection voltage.

12. The method of claim 11, wherein the power switch is an N-type transistor, and the control, channel and reference nodes are a gate, a drain and a source of the N-type transistor respectively.

13. The method of claim 11, comprising:
comparing the controlled voltage with the detection voltage to control the emulation current.

14. The method of claim 11, comprising:
mirroring the emulation current to provide an output current.

15. A composite power switch, comprising:
a control node, a channel node, a reference node, a voltage detection node, and a current detection node; and
first, second and third power switches, each having a gate, a drain and a source, formed on a common substrate;
wherein the gates of the first, second and third power switches are electrically connected to be the control node;
the drains of the first and third power switches are electrically connected to be the channel node;
the sources of the first and second power switches are electrically connected to be the reference node;
the source of the third power switch is the voltage detection node; and
the drain of the second power switch is the current detection node.

16. The composite power switch of claim 15, wherein the drains of the first, second and third power switches are formed within a common active region on the common substrate, and separated by fingers serving as the gates of the first, second and third power switches.

17. The composite power switch of claim 16, wherein the sources of the first, second and third power switches are formed within the common active region.

18. A power supply, comprising:
the composite power switch of claim 15;
an inductor electrically connected to one of the channel node and the reference node; and
a close-loop controller electrically connected to the current detection node and the voltage detection node, for providing an emulation current to the current detection node to equal a controlled voltage at the current detection node equal to the detection voltage.

19. The power supply of claim 18, wherein the close-loop controller comprises a differential amplifier and a controllable current source, the controlled voltage and the detection voltage are provided to the differential amplifier as two inputs to control the controllable current source supplying the emulation current to the current detection node.

20. The power supply of claim 18, wherein the close-loop controller comprises a current mirror to provide an output current mirroring the emulation current as an output of the close-loop controller.
